(19) United States
(12) Patent Application Publication
(10) Pub. No.: US 2015/0153113 A1
(43) Pub. Date: Jun. 4, 2015

(54) HEAT SINK WITH AIR PATHWAYS THROUGH THE BASE

(71) Applicant: International Business Machines Corporation, Armonk, NY (US)

(72) Inventors: Troy W. Glover, Raleigh, NC (US); William M. Megarity, Raleigh, NC (US); Michael S. Purdy, Clayton, NC (US); Whitcomb R. Scott, III, Chapel Hill, NC (US)

(73) Assignee: International Business Machines Corporation, Armonk, NY (US)

(21) Appl. No.: 14/094,843

(22) Filed: Dec. 3, 2013

(51) Int. Cl. F28F 3/04; H05K 1/02; H05K 7/20

(52) U.S. Cl. CPC F28F 3/04; H05K 7/20154; H05K 7/2039; H05K 1/0201

(57) ABSTRACT

A heat sink includes a heat sink base having a central area for contacting a heat-generating component and a perimeter area extending beyond the central area, wherein the perimeter area of the heat sink base includes air pathways through the heat sink base and the central area does not. The heat sink further includes heat sink fins extending from the heat sink base across the central area and the perimeter area. Airflow across the heat sink removes heat from the heat-generating component, such as a processor. The central area may be secured in contact with a surface of a processor operably secured to a circuit board. The heat sink is particularly beneficial in circuit board configurations having a component immediately upstream or downstream of the processor.

### BACKGROUND

1. Field of the Invention

The present invention relates to thermally conductive heat sinks used in cooperation with an air mover to remove heat from a heat source.

2. Background of the Related Art

Computer systems require removal of heat from heat-generating electronic components, such as processors, in order to avoid thermal damage. These heat-generating electronic components are often coupled to a generally planar circuit board, such as a motherboard. Heat generated by the electronic component may be conducted away from the electronic component to a heat sink having a heat sink base and a plurality of fins coupled to the heat sink base to dissipate heat to surrounding air within the computer chassis. Air flow within the chassis may be provided by air movers such as fans installed within a computer chassis, a server rack or within a data center. Air movers are generally fixed and may be coupled to a controller to vary the speed of the air mover as needed to provide sufficient air flow to cool electronic components.

Heat sink fins efficiently dissipate heat to a surrounding air flow when the fins are generally aligned with the air flow. For this reason, air movers are generally positioned to draw air into an inlet end of a chassis, and heat sinks are generally positioned within a chassis to align the fins with the anticipated air flow. However, the size and position on other components within the chassis can affect the air flow to the heat sinks resulting in a loss of heat sink efficiency. In any given chassis design, the component layout and operation may be tested to assure adequate airflow to each component. Still, there is a desire to avoid excessive use of fans, since fan operation can consume significant power and produce significant noise.

### BRIEF SUMMARY

One embodiment of the present invention provides a heat sink, comprising a heat sink base securable to a heat generating component. The heat sink base has a central area for contacting the heat generating component and a perimeter area extending beyond the central area, wherein the perimeter area of the heat sink base includes air pathways through the heat sink base, and wherein the central area of the heat sink base does not include air pathways through the heat sink base. The heat sink further comprises heat sink fins extending from the heat sink base across the central area and the perimeter area.

Another embodiment of the present invention provides an apparatus, comprising a circuit board operably securing a processor, and a heat sink including a heat sink base and a plurality of heat sink fins extending from the heat sink base. The heat sink base has a central area in contact with a surface of the processor and a perimeter area laterally extending beyond the surface of the processor, wherein the perimeter area of the heat sink base includes air pathways through the heat sink base, and wherein the central area of the heat sink base does not include air pathways through the heat sink base.

### BRIEF DESCRIPTION OF THE SEVERAL VIEWS OF THE DRAWINGS

FIG. 1A is a perspective view of a heat sink in accordance with one embodiment of the present invention.

FIG. 1B is a top view of the heat sink of FIG. 1A.

FIG. 2A is a perspective view of the heat sink being used to cool a processor on a circuit board within a chassis where another component is positioned immediately upstream of the processor.

FIGS. 2B-2C are side views of the heat sink, processor and circuit board of FIG. 2A illustrating the air flow pattern facilitated by the airflow pathways through the heat sink base.

FIG. 3A is a perspective view of the heat sink being used to cool a processor on a circuit board within a chassis where another component is positioned immediately downstream of the processor.

FIGS. 3B-3C are side views of the heat sink, processor and circuit board of FIG. 2A illustrating the air flow pattern facilitated by the airflow pathways through the heat sink base.

### DETAILED DESCRIPTION

One embodiment of the present invention provides a heat sink, comprising a heat sink base securable to a heat generating component. The heat sink base has a central area for contacting the heat generating component and a perimeter area extending beyond the central area, wherein the perimeter area of the heat sink base includes air pathways through the heat sink base, and wherein the central area of the heat sink base does not include air pathways through the heat sink base. The heat sink further comprises heat sink fins extending from the heat sink base across the central area and the perimeter area. Optionally, the heat sink may be an extruded heat sink.

The air pathways extend through the heat sink base and may have any shape of perforation, such as circular holes or elongate slots. For example, the air pathways may be slots that are elongate in a direction parallel to the heat sink fins. Furthermore, the air pathways may extend perpendicular to the surfaces of the heat sink base or may extend at an angle. In another option, the air pathways through the heat sink base are limited to areas between the heat sink fins. In yet another option, the air pathways through the heat sink base may be uniformly sized and spaced.

Another embodiment of the present invention provides an apparatus, comprising a circuit board operably securing a processor, and a heat sink including a heat sink base and a plurality of heat sink fins extending from the heat sink base. The heat sink base has a central area in contact with a surface of the processor and a perimeter area laterally extending beyond the surface of the processor, wherein the perimeter area of the heat sink base includes air pathways through the heat sink base, and wherein the central area of the heat sink base does not include air pathways through the heat sink base. The processor is secured to the circuit board and elevates the heat sink above the surface of the circuit board creating a potential for airflow underneath the perimeter area of the heat sink base.

The circuit board may be, for example, a motherboard or an expansion card. The processor is operably secured to the circuit board, such as being receiving in a socket. Optionally, the processor is a bare die, where a surface of the bare die is in contact with the central portion of the heat sink base. The heat sink in contact with the processor may include any one or more of the features described above, such as features of the air pathways through the heat sink base.

Yet another embodiment of the apparatus, further includes a chassis receiving the circuit board, an air mover causing air to flow through the chassis in an airflow direction, and a component operably secured to the circuit board adjacent the processor along an upstream side of the processor. Although the position of the component may prevent or impede airflow from passing underneath an upstream end of the heat sink base, airflow entering between the heat sink fins can pass (downwardly) through the air pathways to the underneath side of the heat sink base. As a result the airflow through the heat sink may increase and provide additional cooling. Optionally, the perimeter area of the heat sink base may have airflow pathways only on the downstream and lateral sides relative to the processor, since the airflow pathways on the upstream side relative to the processor are substantially blocked.

In an alternative to the previous embodiment, the apparatus may further include a chassis receiving the circuit board, an air mover causing air to flow through the chassis in an airflow direction, and a component operably secured to the circuit board adjacent the processor along a downstream side of the processor. Although the position of the component may prevent or impede airflow underneath the heat sink base from exiting along the downstream end of the heat sink base, airflow underneath the heat sink base can pass (upwardly) through the air pathways to the top side of the heat sink base. Optionally, the perimeter area of the heat sink base may have airflow pathways only on the upstream and lateral sides relative to the processor, since the air pathways on the downstream side relative to the processor are substantially blocked.

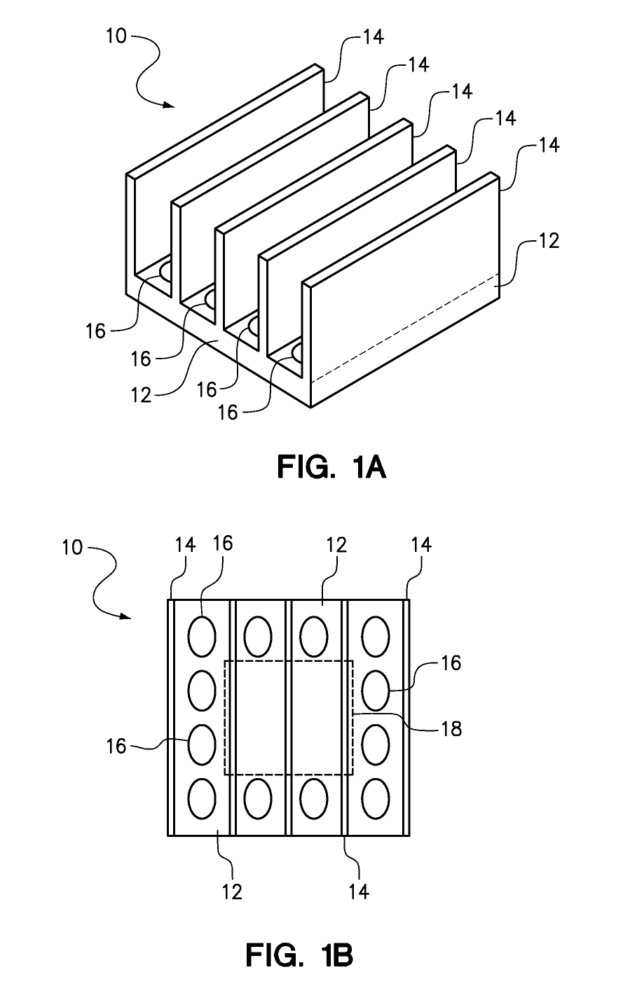

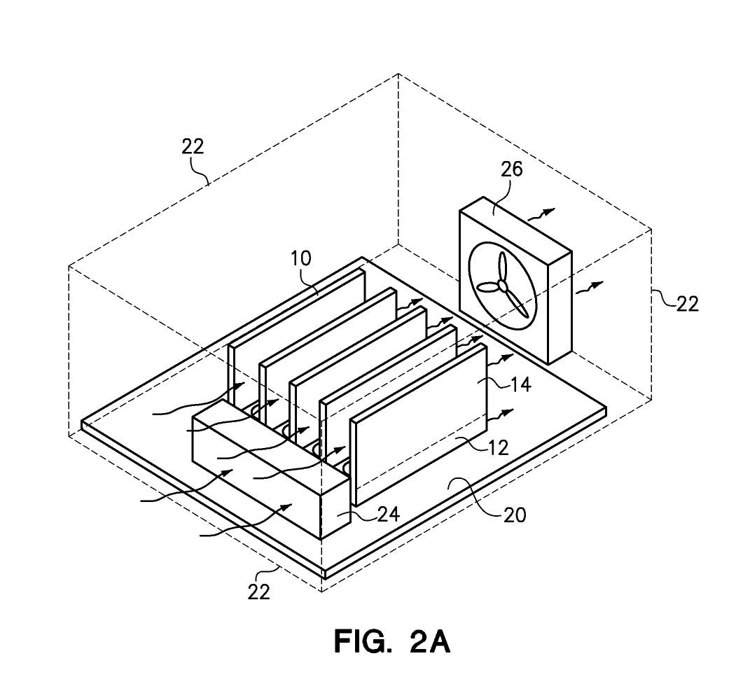

FIG. 1A is a perspective view of a heat sink 10 in accordance with one embodiment of the present invention. The heat sink 10 includes a heat sink base 12 and a plurality of heat sink fins 14 extending from the heat sink base 12. In FIG. 1A, the heat sink base 12 is the thicker, horizontal portion of the heat sink 10 and the heat sink fins 14 are the thinner, vertical portion of the heat sink 10. The heat sink is made with a material having a high thermal conductivity in order to conduct heat away from a component in contact with the lower surface of the heat sink base 12. The heat sink base 12 then distributes the heat to the heat sink fins 14. Air flowing across the heat sink base 12 and the high surface-area heat sink fins 14 will take on the heat from the heat sink. In this view, it is possible to see the end of several air pathways 16 through the heat sink base 12.

FIG. 1B is a top view of the heat sink 10 of FIG. 1A. The fins 14 are spaced apart across the top surface of the heat sink base 12. The surface area of the heat sink base 12 may be described as having two regions or areas—namely, a contact area 18 (enclosed by dashed lines) and a perimeter area which extends around the central contact area. The contact area 18 preferably has no air pathways since contact with a heat-generating component, such as a processor, would block the lower end of such air pathways anyway and having no perforations in the contact area allows more heat to be conducted away from the heat generating component. As shown, each air pathway 16 in the perimeter area (outside the contact area 18) is in the shape of a slot that is elongated in a direction parallel to the fins 14, and the air pathways 16 are formed in the areas between the heat sink fins 16.

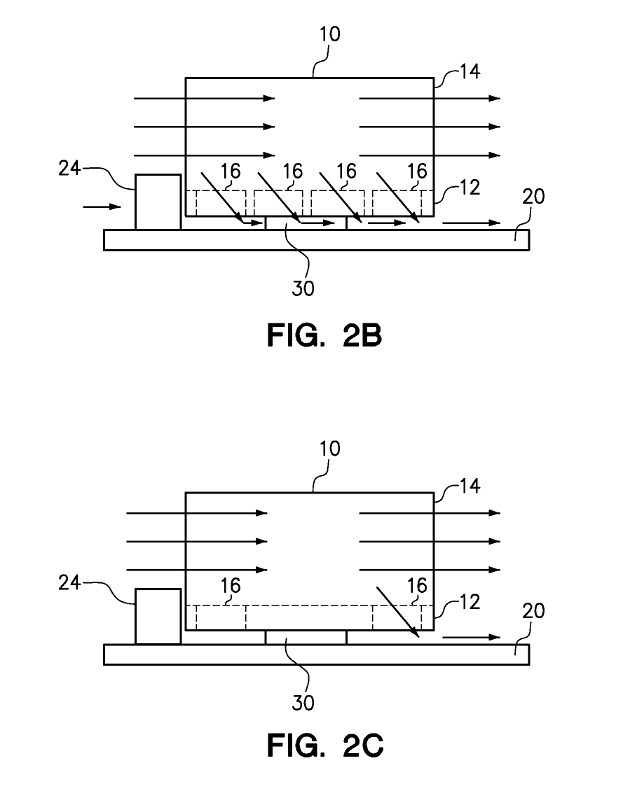

FIG. 2A is a perspective view of the heat sink 10 being used to cool a processor (see the processor 30 underneath the heat sink 10 in FIGS. 2B-2C) on a circuit board 20 within a chassis 22 (see dashed outline) where another component 24 is positioned immediately upstream of the processor. The chassis 22 includes a fan or fan assembly 26 that draws air through the chassis 22 and establishes an airflow direction. In FIG. 2A, the fan is moving air from left to right, such that the component 24 is positioned upstream of the heat sink 10 and processor.

Air flowing into the chassis 22 along the surface of the circuit board 20 encounters impedance at the point of the component 24 and must flow up and over the component 24. This impedance generally reduces the efficiency of the heat sink 10, since less total air is allowed to flow across, over and under the heat sink. The effect of air pathways through the heat sink base, in accordance with one embodiment of the present invention, is shown in FIGS. 2B-2C.

FIGS. 2B-2C are side views of the heat sink 10, processor 30 and circuit board 20 consistent with FIG. 2A illustrating an air flow pattern facilitated by the airflow pathways 16 through the heat sink base 12. The arrows in FIGS. 2B-2C illustrate air flowing through the chassis. Air flowing along the upper edge of the fins 14 encounters little or no impedance and may pass straight across the fins 14 from the upstream end to the downstream end of the fins 14. Unfortunately, the air flowing along the circuit board 20 is blocked by the component 24, such that air cannot flow directly into the region around the processor 30 between the heat sink base 12 and the circuit board 20.

FIG. 2B is a diagram showing four air pathways 16 as shown on the left and right of the top view in FIG. 1B. The air pathways 16 allow air flowing over the component 24 to pass downwardly into the region around the processor 30 between the heat sink base 12 and the circuit board 20. Since these air pathways are not aligned with the processor 30 in the airflow direction (i.e., these air pathways are positioned to the right or left side of the processor and contact area), air may pass through any or all of the air pathways shown. Accordingly, the total amount of airflow through the heat sink may increase and the air passing under the heat sink base and around the processor may remove heat from an area where temperatures are the greatest.

FIG. 2C is a diagram showing two air pathways 16 as shown in the middle of the top view in FIG. 1B. The most-downstream of the two air pathways 16 allows air flowing over the component 24 to pass downwardly into the region behind (downstream of) the processor 30 between the heat sink base 12 and the circuit board 20. However, since the two air pathways are aligned with the processor 30 in the airflow direction, there may be considerable impedance preventing air from pass through the most-upstream of the air pathways shown. Still, the total amount of airflow through the heat sink may increase and the air passing under the heat sink base near the processor may remove heat from an area where temperatures are the greatest.

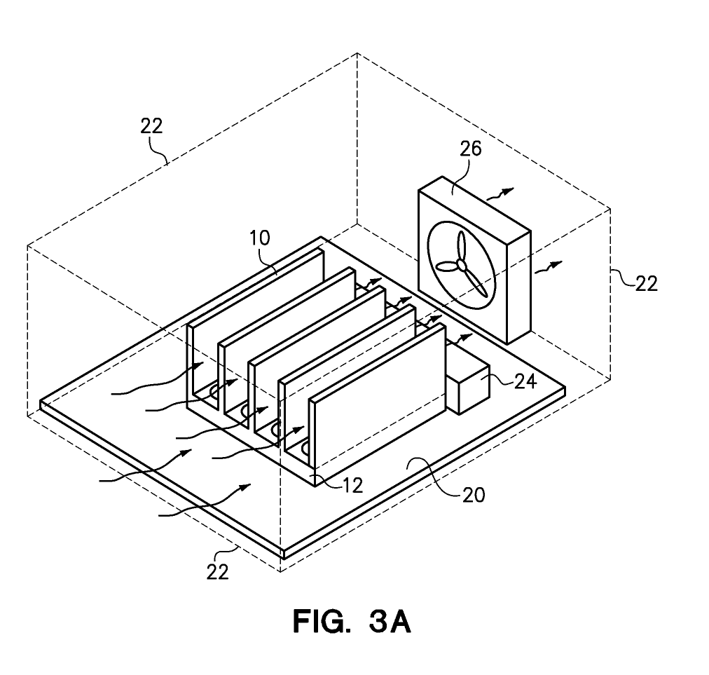

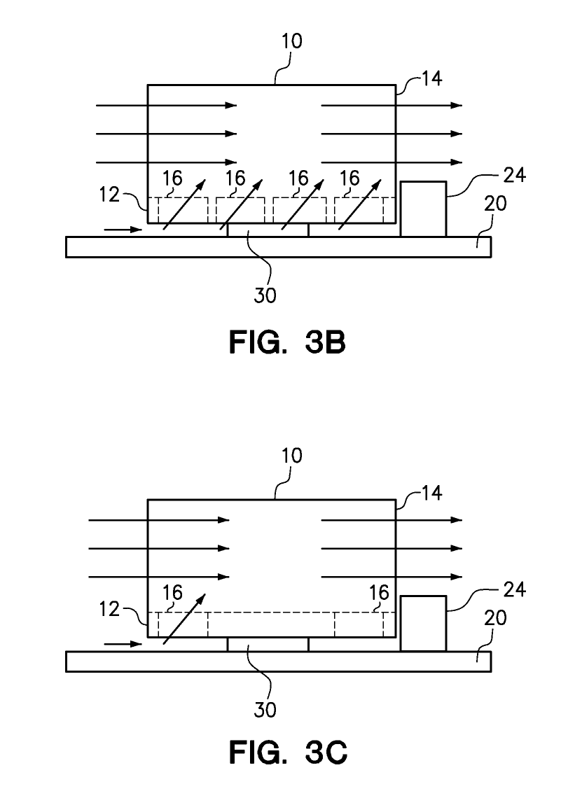

FIG. 3A is a perspective view of the heat sink 10 being used to cool a processor (see the processor 30 underneath the heat sink 10 in FIGS. 3B-3C) on the circuit board 20 within the chassis 22 (see dashed outline) where another component 24 is positioned immediately downstream of the processor. The chassis 22 includes a fan or fan assembly 26 that draws air through the chassis 22 and establishes an airflow direction. In FIG. 3A, the fan is moving air from left to right, such that the component 24 is positioned downstream of the heat sink 10 and processor.

Air flowing into the chassis 22 along the surface of the circuit board 20 passes freely between the heat sink base 12 and the circuit board 20 until the air encounters impedance at the point of the component 24. This impedance generally reduces the efficiency of the heat sink 10, since less total air is allowed to flow across, over and under the heat sink. The effect of air pathways through the heat sink base, in accordance with one embodiment of the present invention, is shown in FIGS. 3B-3C.

FIGS. 3B-3C are side views of the heat sink 10, processor 30 and circuit board 20 of FIG. 3A illustrating an air flow pattern facilitated by the airflow pathways 16 through the heat sink base 12. The arrows in FIGS. 3B-3C illustrate air flowing through the chassis. Air flowing along the upper edge of the fins 14 encounters little or no impedance and may pass straight across the fins 14 from the upstream end to the downstream end of the fins 14. Unfortunately, the air flowing between the heat sink base 12 and the circuit board 20 is blocked by the component 24, such that air cannot directly exit the region around the processor 30 between the heat sink base 12 and the circuit board 20.

FIG. 3B is a diagram showing four air pathways 16 as shown on the left and right of the top view in FIG. 1B. The air pathways 16 allow air flowing through the region around the processor 30 between the heat sink base 12 and the circuit board 20 to pass upwardly through the heat sink base 12 and pass over the component 24. Since these air pathways are not aligned with the processor 30 in the airflow direction (i.e., these air pathways are positioned to the right or left side of the processor and contact area, per FIG. 1B), air may pass through any or all of the air pathways shown. Accordingly, the total amount of airflow through the heat sink may increase and the air passing under the heat sink base and around the processor may remove heat from an area where temperatures are the greatest.

FIG. 3C is a diagram showing two air pathways 16 as shown in the middle of the top view in FIG. 1B. The most-upstream of the two air pathways 16 allows air flowing under the heat sink base 12 to pass upwardly into the area between the heat sink fins 14. However, since the two air pathways are aligned with the processor 30 in the airflow direction, there may be considerable impedance preventing air from passing through the most-downstream of the air pathways shown. Still, the total amount of airflow through the heat sink may increase and the air passing under the heat sink base near the processor may remove heat from an area where temperatures are the greatest.

It should be recognized that in configurations where the position of the component 24 is known, it may be preferably to eliminate the air pathways that lie directed between the processor 30 (or the corresponding contact area 18) and the component 24. Eliminating these air pathways will have a negligible effect on air flow and will increase the heat spreading capacity of the heat sink base.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, components and/or groups, but do not preclude the presence or addition of one or more other features, integers, steps, operations, elements, components, and/or groups thereof. The terms “preferably,” “preferred,” “prefer,” “optionally,” “may,” and similar terms are used to indicate that an item, condition or step being referred to is an optional (not required) feature of the invention.

The corresponding structures, materials, acts, and equivalents of all means or steps plus function elements in the claims below are intended to include any structure, material, or act for performing the function in combination with other claimed elements as specifically claimed. The description of the present invention has been presented for purposes of illustration and description, but it is not intended to be exhaustive or limited to the invention in the form disclosed. Many modifications and variations will be apparent to those of ordinary skill in the art without departing from the scope and spirit of the invention. The embodiment was chosen and described in order to best explain the principles of the invention and the practical application, and to enable others of ordinary skill in the art to understand the invention for various embodiments with various modifications as are suited to the particular use contemplated.

What is claimed is:

1. A heat sink, comprising:
a heat sink base securable to a heat generating component, wherein the heat sink base has a central area for contacting the heat generating component and a perimeter area extending beyond the central area, wherein the perimeter area of the heat sink base includes air pathways through the heat sink base, and wherein the central area of the heat sink base does not include air pathways through the heat sink base; and
heat sink fins extending from the heat sink base across the central area and the perimeter area.

2. The apparatus of claim 1, wherein the air pathways are slots that are elongate in a direction parallel to the heat sink fins.

3. The apparatus of claim 1, wherein the air pathways through the heat sink base are limited to areas between the heat sink fins.

4. The apparatus of claim 1, wherein the air pathways through the heat sink base are uniformly sized and spaced.

5. The apparatus of claim 1, wherein the heat sink is an extruded heat sink.

6. An apparatus, comprising:
a circuit board operably securing a processor;
a heat sink including a heat sink base and a plurality of heat sink fins extending from the heat sink base, wherein the heat sink base has a central area in contact with an surface of the processor and a perimeter area laterally extending beyond the surface of the processor, wherein the perimeter area of the heat sink base includes air pathways through the heat sink base, and wherein the central area of the heat sink base does not include air pathways through the heat sink base.

7. The apparatus of claim 6, wherein the air pathways are slots that are elongate in a direction parallel to the heat sink fins.

8. The apparatus of claim 6, wherein the air pathways through the heat sink base are limited to areas between the heat sink fins.

9. The apparatus of claim 6, wherein the air pathways through the heat sink base are uniformly sized and spaced

10. The apparatus of claim 6, wherein the heat sink is an extruded heat sink.

11. The apparatus of claim 6, wherein the processor is a bare die.

12. The apparatus of claim 6, further comprising:
a chassis receiving the circuit board;
an air mover causing air to flow through the chassis in an airflow direction; and
a component operably secured to the circuit board adjacent the processor along an upstream side of the processor preventing airflow from passing underneath an upstream end of the heat sink base, wherein airflow entering between the heat sink fins can pass through the air pathways to the underneath side of the heat sink base.

13. The apparatus of claim 12, wherein the perimeter area of the heat sink base has airflow pathways only on the downstream and lateral sides relative to the processor.

14. The apparatus of claim 6, further comprising:
a chassis receiving the circuit board;
an air mover causing air to flow through the chassis in an airflow direction; and
a component operably secured to the circuit board adjacent the processor along a downstream side of the processor preventing airflow underneath the heat sink base from exiting along the downstream end of the heat sink base, wherein airflow underneath the heat sink base can pass through the air pathways to the top side of the heat sink base.

15. The apparatus of claim 14, wherein the perimeter area of the heat sink base has airflow pathways only on the upstream and lateral sides relative to the processor.
